(19) United States
(12) Patent Application Publication
(10) Pub. No.: US 2023/0411477 A1
(43) Pub. Date: Dec. 21, 2023

(54) STEPPED SOURCE DRAIN CONTACT FOR GATE-ALL-AROUND TRANSISTOR

(71) Applicant: INTERNATIONAL BUSINESS MACHINES CORPORATION, ARMONK, NY (US)

(72) Inventors: Su Chen Fan, Cohoes, NY (US); Nicolas Jean Loubet, GUILDERLAND, NY (US); Yann Mignot, Slingerlands, NY (US); Tsung-Sheng Kang, Ballston Lake, NY (US); Eric Miller, Watervliet, NY (US)

(21) Appl. No.: 17/807,873

(22) Filed: Jun. 21, 2022

(51) Int. Cl. H01L 29/423; H01L 29/06; H01L 29/786; H01L 29/45; H01L 29/417

(52) U.S. Cl. CPC H01L 29/42392; H01L 29/0665; H01L 29/41775; H01L 29/458; H01L 29/78696

(57) ABSTRACT

A gate-all-around transistor structure including a channel region surrounded on three sides by a gate conductor, and a pair of salicide regions extending from opposite ends of the channel region in a direction parallel with the gate conductor.

### BACKGROUND

The present invention generally relates to semiconductor structures, and more particularly to gate-all-around transistor structures having stepped source drawn contacts.

Integrated circuit (IC) chips are formed on semiconductor wafers at increasingly smaller scale. In current technology nodes, such as 7, 10 and 14 nanometer technologies, transistor devices are constructed as three-dimensional (3D) fin field effect transistor (FINFET) structures. However, chipmakers face a myriad of challenges at 5 nm, 3 nm and beyond. Currently, traditional chip scaling continues to slow as process complexities and costs escalate at each node. A potential solution to this chip scaling problem is gate-all-around technology.

### SUMMARY

According to an embodiment of the present invention, a gate-all-around transistor structure is provided. The gate-all-around transistor structure may include a channel region surrounded on three sides by a gate conductor, and a pair of salicide regions extending from opposite ends of the channel region in a direction parallel with the gate conductor.

According to another embodiment of the present invention, a gate-all-around transistor structure is provided. The gate-all-around transistor structure may include a plurality of channel regions surrounded on three sides by a gate conductor; and a plurality of salicide regions extending from opposite ends of the plurality of channel regions in a direction parallel with the gate conductor.

According to another embodiment of the present invention, a gate-all-around transistor structure is provided. The gate-all-around transistor structure may include a plurality of nanosheet channel regions surrounded on three sides by a gate conductor, and a pair of salicide regions extending from opposite ends of each of the plurality of channel regions in a direction parallel with the gate conductor, wherein each pair of salicide regions extend different distances from the opposite ends of each of the plurality of channel regions.

### BRIEF DESCRIPTION OF THE DRAWINGS

The following detailed description, given by way of example and not intended to limit the invention solely thereto, will best be appreciated in conjunction with the accompanying drawings, in which:

FIGS. 1, 2, and 3, depict a structure during an intermediate step of a method of fabricating a stacked transistor structure according to an embodiment of the invention;

FIGS. 4, 5, 6, 7, and 8, depict the structure after forming sacrificial gate lines, gate spacers, and inner spacers according to an embodiment of the invention;

FIGS. 9, 10, 11, 12, and 13, depict the structure after forming salicide regions according to an embodiment of the invention;

FIGS. 14, 15, 16, 17, and 18, depict the structure after forming a dielectric layer and a gate cut region according to an embodiment of the invention;

FIGS. 19, 20, 21, 22, and 23, the structure is shown after forming a gate conductor according to an embodiment of the invention; and

FIGS. 24, 25, 26, 27, and 28, the structure is shown after forming a middle-of-line dielectric, gate contacts, and source drain contacts according to an embodiment of the invention.

The drawings are not necessarily to scale. The drawings are merely schematic representations, not intended to portray specific parameters of the invention. For clarity and ease of illustration, scale of elements may be exaggerated. The drawings are intended to depict only typical embodiments of the invention. In the drawings, like numbering represents like elements.

Additionally, XYZ Cartesian coordinates may be also shown in each of the drawings to provide additional spatial context. The terms “vertical” or “vertical direction” or “vertical height” as used herein denote a Z-direction of the Cartesian coordinates shown in the drawings, and the terms “horizontal,” or “horizontal direction,” or “lateral direction” as used herein denote an X-direction and/or a Y-direction of the Cartesian coordinates shown in the drawings.

### DETAILED DESCRIPTION

Detailed embodiments of the claimed structures and methods are disclosed herein; however, it can be understood that the disclosed embodiments are merely illustrative of the claimed structures and methods that may be embodied in various forms. This invention may, however, be embodied in many different forms and should not be construed as limited to the exemplary embodiments set forth herein. In the description, details of well-known features and techniques may be omitted to avoid unnecessarily obscuring the presented embodiments.

References in the specification to “one embodiment”, “an embodiment”, “an example embodiment”, etc., indicate that the embodiment described may include a particular feature, structure, or characteristic, but every embodiment may not necessarily include the particular feature, structure, or characteristic. Moreover, such phrases are not necessarily referring to the same embodiment. Further, when a particular feature, structure, or characteristic is described in connection with an embodiment, it is submitted that it is within the knowledge of one skilled in the art to affect such feature, structure, or characteristic in connection with other embodiments whether or not explicitly described.

For purposes of the description hereinafter, the terms “upper”, “lower”, “right”, “left”, “vertical”, “horizontal”, “top”, “bottom”, and derivatives thereof shall relate to the disclosed structures and methods, as oriented in the drawing figures. It will be understood that when an element as a layer, region or substrate is referred to as being “on” or “over” another element, it can be directly on the other element or intervening elements may also be present. In contrast, when an element is referred to as being “directly on” or “directly over” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. Also, the term “sub-lithographic” may refer to a dimension or size less than current dimensions achievable by photolithographic processes, and the term “lithographic” may refer to a dimension or size equal to or greater than current dimensions achievable by photolithographic processes. The sub-lithographic and lithographic dimensions may be determined by a person of ordinary skill in the art at the time the application is filed.

The terms substantially, substantially similar, about, or any other term denoting functionally equivalent similarities refer to instances in which the difference in length, height, or orientation convey no practical difference between the definite recitation (e.g. the phrase sans the substantially similar term), and the substantially similar variations. In one embodiment, substantial (and its derivatives) denote a difference by a generally accepted engineering or manufacturing tolerance for similar devices, up to, for example, 10% deviation in value or 10° deviation in angle.

In the interest of not obscuring the presentation of embodiments of the present invention, in the following detailed description, some processing steps or operations that are known in the art may have been combined together for presentation and for illustration purposes and in some instances may have not been described in detail. In other instances, some processing steps or operations that are known in the art may not be described at all. It should be understood that the following description is rather focused on the distinctive features or elements of various embodiments of the present invention.

Complementary field effect transistors, or gate-all-around transistors, have known advantages over conventional transistor structures in terms of density, performance, power consumption, and integration. However, conventional gate-all-around devices having source drain epitaxy regions grown from channels ends between cells suffer from high resistance cause by the relatively large source drain epitaxy regions and the relatively small contact area between the channel ends and the source drain epitaxy.

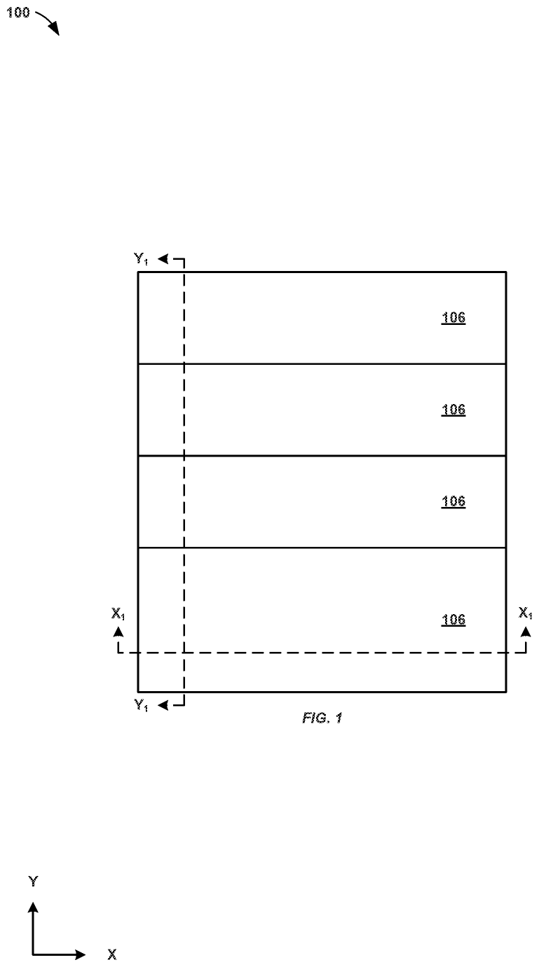

The present invention generally relates to semiconductor structures, and more particularly to gate-all-around transistor structures having stepped source drain contacts. More specifically, the transistor structures and associated method disclosed herein enables a novel solution for providing source drain contacts to individual to stepped silicided channel ends. Exemplary embodiments of transistors having stepped source drain contacts are described in detail below by referring to the accompanying drawings in FIGS. 1 to 28. Those skilled in the art will readily appreciate that the detailed description given herein with respect to these figures is for explanatory purposes as the invention extends beyond these limited embodiments.

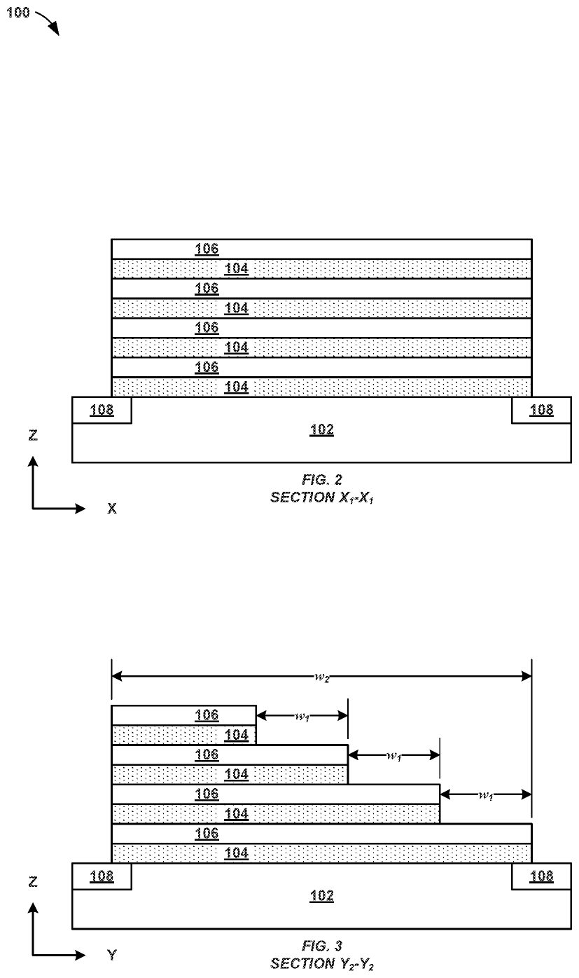

Referring now to FIGS. 1, 2, and 3, a structure 100 is shown during an intermediate step of a method of fabricating a stacked transistor structure according to an embodiment of the invention. FIG. 1 is a representative illustration of a top view of the structure 100 omitting some materials and layers, for example, patterning layers, masking layers and interlevel dielectrics. As such, only pertinent conductive layers and components are shown to provide a clear understanding of their relative orientation. FIG. 2 depicts a cross-sectional view of the structure 100 shown in FIG. 1 taken along line X₁-Xi. FIG. 3 depicts a cross-sectional view of the structure 100 shown in FIG. 1 taken along line Y₁-Yi.

The structure 100 illustrated in FIG. includes a plurality of nanosheet layers formed on a substrate 102 in accordance with known techniques. Specifically, the plurality of nanosheet layers includes an alternating series of sacrificial nanosheets 104 and channel nanosheets 106 deposited or grown one after another on the substrate 102. For example, the sacrificial nanosheets 104 may be silicon germanium (SiGe) while the channel nanosheets 106 may be silicon (Si) doped with phosphorus, arsenic, or both. Although only six alternating nanosheets (104, 106) are shown, one or more additional sacrificial nanosheets and/or channel nanosheets can optionally be epitaxially grown in an alternating fashion, and the properties of any additional nanosheets are the same as the corresponding nanosheets described herein. Additionally, active regions are defined by patterning the plurality of nanosheet layers into “fins”, and shallow trench isolation features 108 are formed according to known techniques.

After the plurality of nanosheet layers formed on the substrate 102, they are patterned using a series of masking and etching techniques to create a “stair”, or “stepped”, formation, as illustrated in FIG. 3. More specifically, a top surface at one end of each channel nanosheet 106 is exposed. In doing so, upper layers are etched to expose portions of underlying layers in a sequential fashion. For purposed of the present disclosure, exposed portions of each channel nanosheet 106 should be at least 5˜30 nm wide (w₁), measured in the y-direction. Further, a total width (w₂) of the plurality of nanosheet layers is a least the sum of (a) minimum channel width and (b) three contacts, as illustrated in the present example. Therefore, the total width (w 2) of the plurality of nanosheet layers may range from about 50 to about 500 nm.

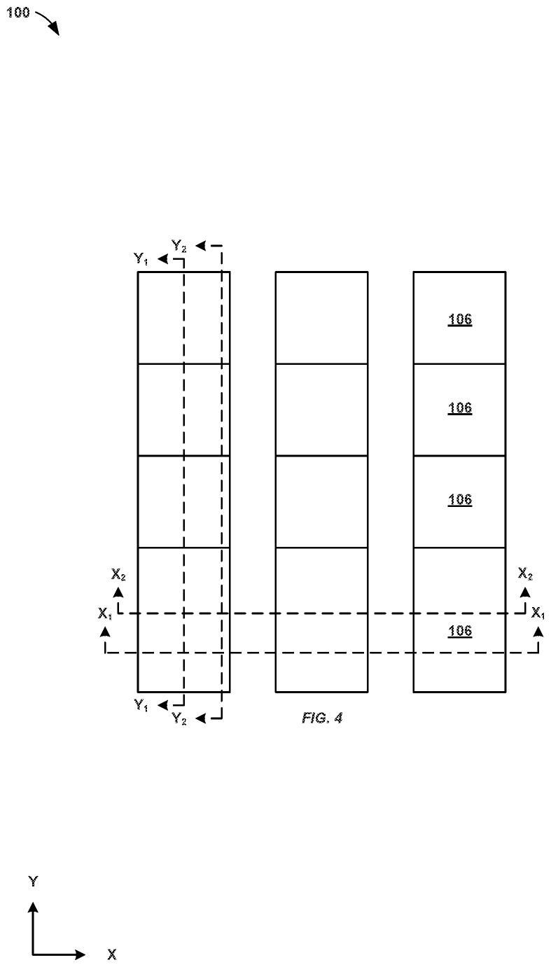

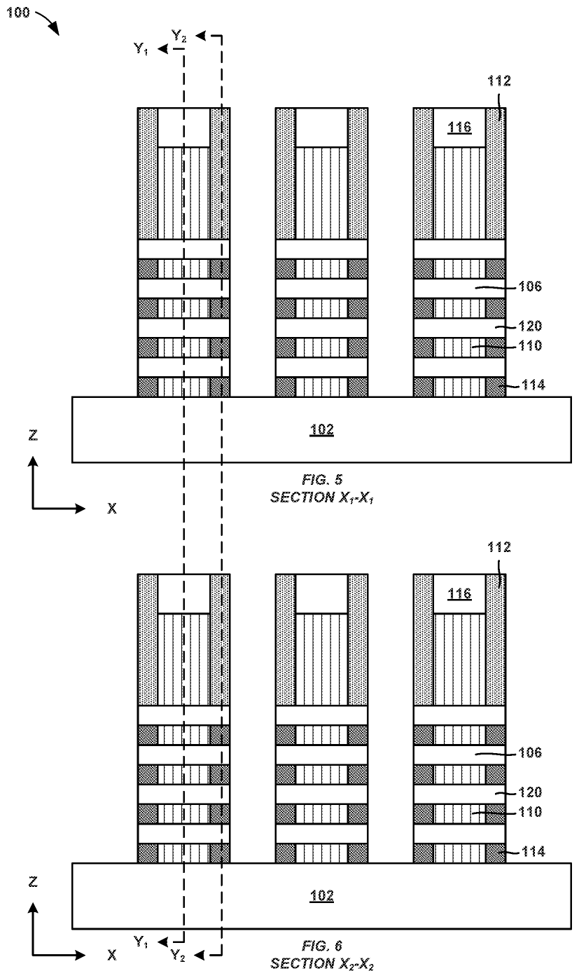

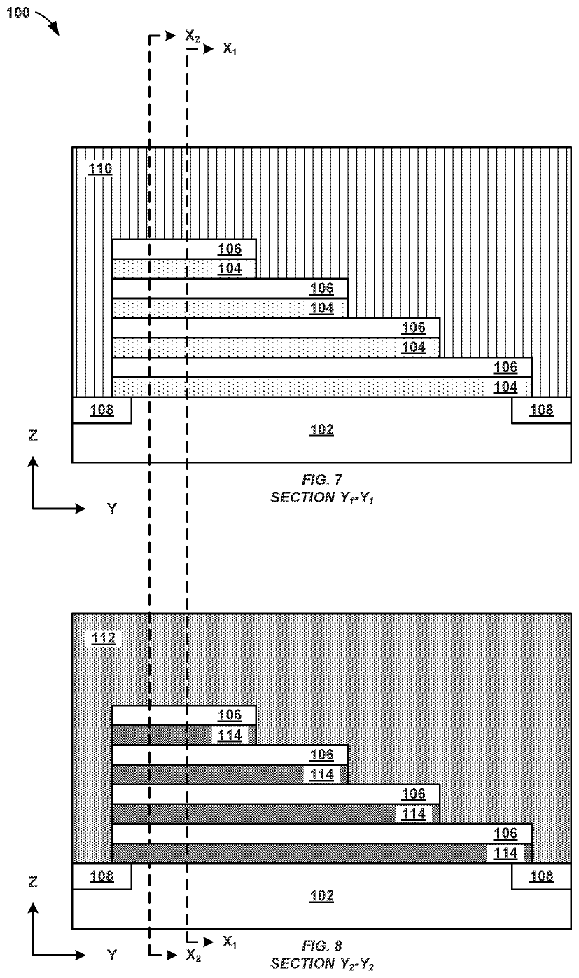

Referring now to FIGS. 4, 5, 6, 7, and 8, the structure 100 is shown after forming sacrificial gate lines 110, gate spacers 112, and inner spacers 114 according to an embodiment of the invention. FIG. 4 is a representative illustration of a top view of the structure 100 omitting some features as described above with reference to FIG. 1. FIG. 5 depicts a cross-sectional view of the structure 100 shown in FIG. 4 taken along line X₁-X₁. FIG. 6 depicts a cross-sectional view of the structure 100 shown in FIG. 4 taken along line X₂-X₂. FIG. 7 depicts a cross-sectional view of the structure 100 shown in FIG. 4 taken along line Y₁-Yi. FIG. 8 depicts a cross-sectional view of the structure 100 shown in FIG. 4 taken along line Y₂-Y₂. It is noted, at this stage of fabrication cross-sections of FIG. 5 and FIG. 6 are identical.

The sacrificial gate lines 110, gate spacers 112, and inner spacers 114 are formed using conventional techniques well known be persons having ordinary skill in the art. For example, the sacrificial gate lines 110 are first patterned perpendicular to the nanosheet fins using a hardmask 116. Next, the gate spacers 112 are disposed on opposite and exposed sidewalls of each the sacrificial gate lines 110 and the nanosheet fins in a typical fashion. Additionally, the sacrificial nanosheets 104 are laterally recessed beneath the sacrificial gate lines 110 and the inner spacers 112 are formed according to known techniques. The inner spacers 112 separate subsequently formed metal gate lines from adjacent structures.

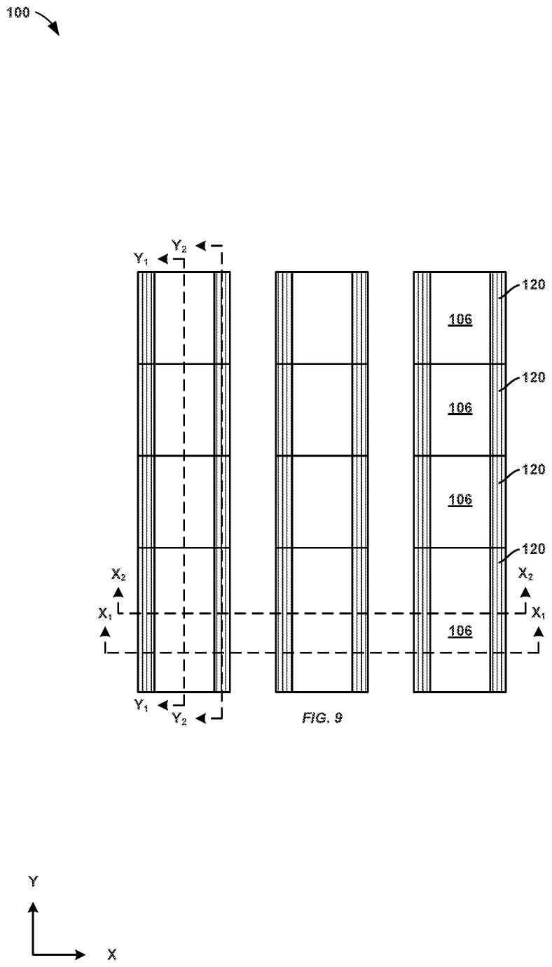

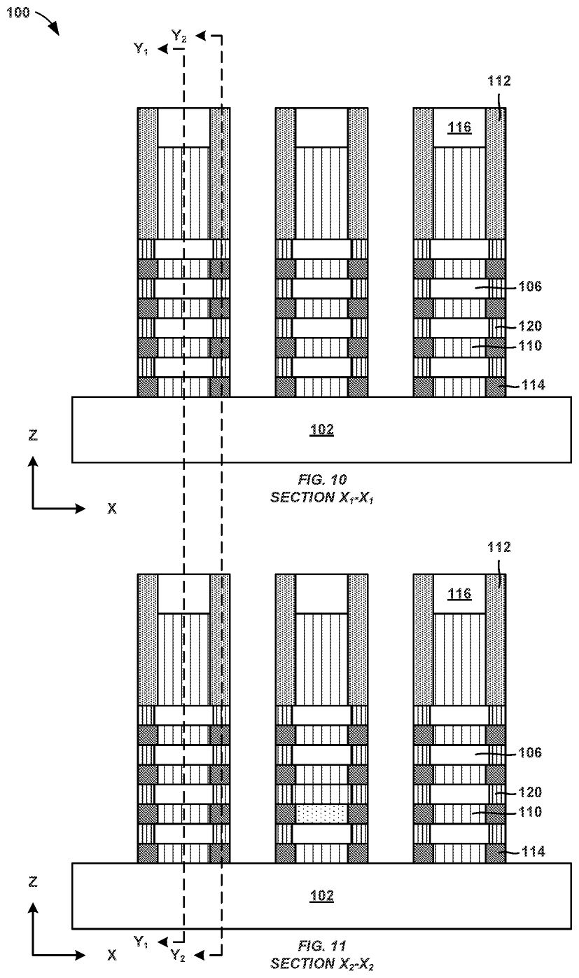

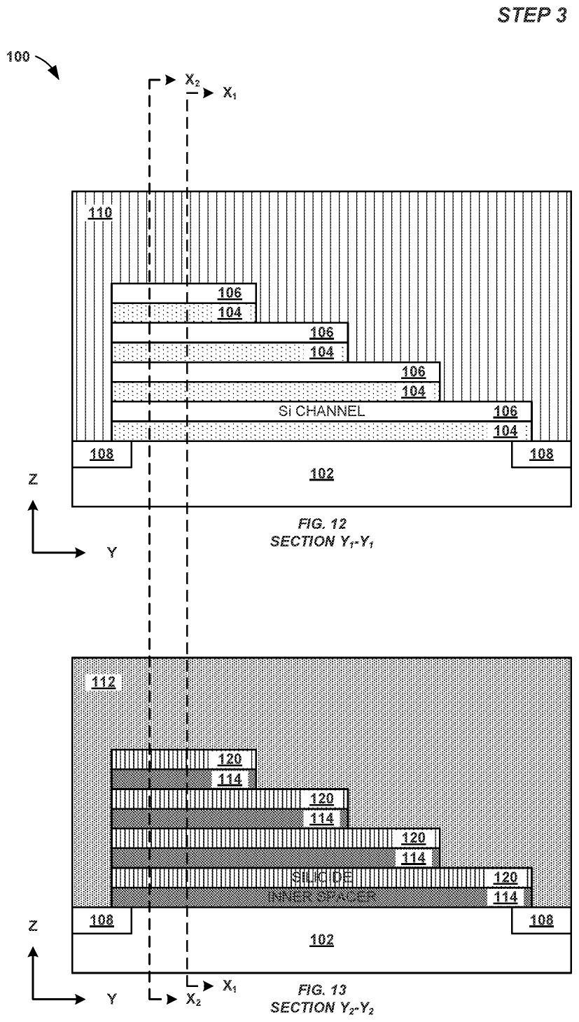

Referring now to FIGS. 9, 10, 11, 12, and 13, the structure 100 is shown after forming salicide regions 118 according to an embodiment of the invention. FIG. 9 is a representative illustration of a top view of the structure 100 omitting some features as described above with reference to FIG. 1. FIG. 10 depicts a cross-sectional view of the structure 100 shown in FIG. 9 taken along line X₁-X₁. FIG. 11 depicts a cross-sectional view of the structure 100 shown in FIG. 9 taken along line X₂-X₂. FIG. 12 depicts a cross-sectional view of the structure 100 shown in FIG. 9 taken along line Y₁-Y₁. FIG. 13 depicts a cross-sectional view of the structure 100 shown in FIG. 9 taken along line Y₂-Y₂.

The salicide regions 118 are formed from exposed ends of the channel nanosheets 106 using known self-aligned salicidation techniques. First, for example, a metal layer, or metal alloy layer, (not shown) is conformally deposited in the opening between adjacent cells, and specifically on exposed ends, or sidewalls, of the channel nanosheets 106. The metal layer may be formed using any suitable deposition technique known in the art including, but not limited to: chemical vapor deposition (CVD), plasma-assisted CVD, metal-organic CVD, high-density chemical vapor deposition (HDCVD), selective CVD, atomic layer deposition (ALD), plating, sputtering, evaporation, and chemical solution deposition. Deposition of the metal layer may be continued until an initial thickness of about 25 nm or less, preferably about 15 nm or less, even more preferably about 5 nm or less, is produced. The thickness of the metal layer will affect the size of the salicide regions 118, as described below.

In an embodiment, the metal layer may include a nickel-platinum (NiPt) alloy. The metal alloy layer may include a nickel concentration ranging from about 70 to about 95 atomic percent. Preferably, nickel may be present in the alloy in an amount ranging from about 90 to about 95 atomic percent. The remainder may be platinum and, if present, another metal. In other embodiments, the metal layer may include NiPd, NiRe, Ti, TiTa, TiNb, W, or Co.

The other metal or alloying additive that can be optionally present in the NiPt alloy layer may include Pd, Rh, Ti, V, Cr, Zr, Nb, Mo, Ht, Ta, W, or Re. In an embodiment, the other alloying additive may be Re or W. When present, the alloying additive is present in an amount ranging from about 0 to about 50 atomic percent with an amount ranging from about 0.1 to about 20 atomic percent being more typical. More preferably, the other metal is present in an amount ranging from about 0.5 to about 10 atomic percent.

Next, an annealing step may be carried out to allow the metal to react with the silicon and form a silicide. It is understood this annealing step temperature will be adjusted depending on the type of metal used for silicide formation. The annealing step may be performed at relatively low annealing temperature, ranging from about 150° C. to about 500° C., for a duration ranging from about 1 second to about 1000 seconds or alternatively at a higher anneal temperature, ranging from 500° C. to 1000° C. for a shorter amount of time, typically for a duration ranging from 1 second to 10 seconds. The annealing step may be using either a continuous heating regime or various ramp and soak heating cycles.

The annealing step, as described above, may be generally referred to as a rapid thermal annealing (RTA) step. As a result of the RTA step, nickel contained in the portions of the metal layer in contact with sidewalls of the channel nanosheets 106 reacts with silicon contained in the channel nanosheets 106 to form the salicide regions 118. The salicide regions 118 may include, at a minimum, nickel and silicon. In some embodiments, the nickel salicides may also include another metal or alloying additive as discussed above. The salicide regions 118 formed after the RTA step, may extend laterally into the silicon material of the channel nanosheets 106 about equal to or less than a length of the inner spacers 114. If a length of the salicide regions 118, in the x-direction, is less than or equal to a length of the inner spacers 114, in the x-direction, then the parasitic resistance is reduced as the channel is directed contacted to salicide regions 118, unlike conventional structure which is contacted to epitaxy, then epitaxy contacted to silicide. If a length of the salicide regions 118, in the x-direction, is greater than a length of the inner spacers 114, in the x-direction, then the channel is shorter and the risk of shorting source to drain through the silicided channel is high. If the channel is shorted, the device will be a resistor instead of a transistor. Finally, any suitable etching technique known in the art may be used to remove an unreacted portion of the metal alloy layer remaining on any non-silicon containing surfaces.

Finally, because the salicide regions 118 are formed from portions of the channel nanosheets 106, they are in direct contact with the channel regions 124, and thus operate as source drain regions of the cell.

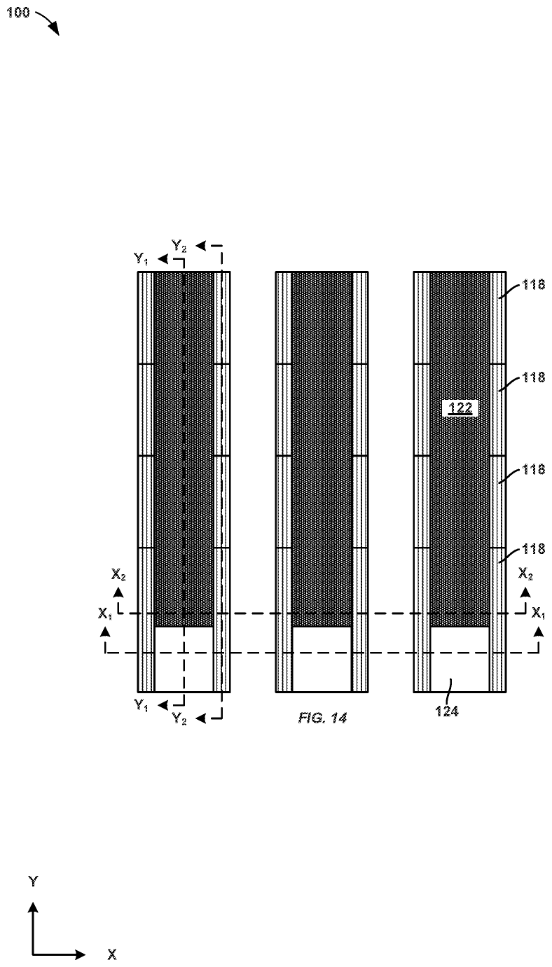

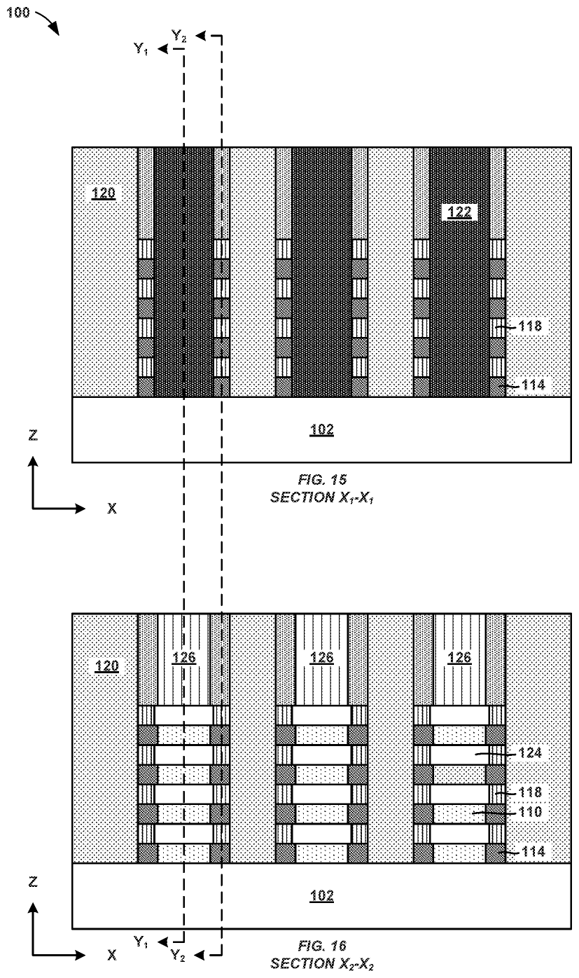

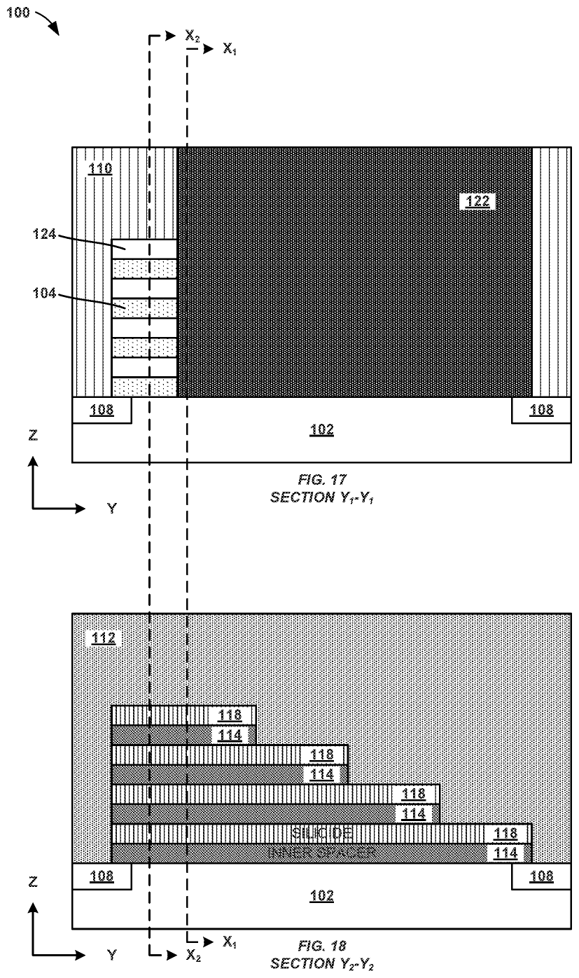

Referring now to FIGS. 14, 15, 16, 17, and 18, the structure 100 is shown after forming a dielectric layer 120 and a gate cut region 122 according to an embodiment of the invention. FIG. 14 is a representative illustration of a top view of the structure 100 omitting some features as described above with reference to FIG. 1. FIG. 15 depicts a cross-sectional view of the structure 100 shown in FIG. 14 taken along line X₁-X₁. FIG. 16 depicts a cross-sectional view of the structure 100 shown in FIG. 14 taken along line X₂-X₂. FIG. 17 depicts a cross-sectional view of the structure 100 shown in FIG. 14 taken along line Y₁-Yi. FIG. 18 depicts a cross-sectional view of the structure 100 shown in FIG. 14 taken along line Y₂-Y₂.

First, a gate cut opening is formed in the sacrificial gate lines 110 using known patterning and etching techniques. Specifically, the gate cut opening is self-aligned between the gate spacers 112 and positioned to substantially remove the stepped portions of the plurality of nanosheets, after which a neat vertical stack of nanosheets remains. It is noted the gate spacers 112, the inner spacers 114, and the salicide regions 118 are not removed when forming the gate cut opening, as illustrated in FIG. 15. Additionally, the inner spacers 114 and the salicide regions 118 beneath the gate spacers 112 will remain in the stepped formation, as illustrated in FIG. 18.

Next, a dielectric layer 120 is blanket deposited across the structure 100. Specifically, the dielectric layer 120 fills the gate cut opening and the space between cells. As described herein, the gate cut opening filled with the dielectric layer 120 is referred to as the gate cut region 122. In an embodiment, the dielectric layer 120 can be any known interlevel dielectric material. In at least one embodiment, the dielectric layer 120 may include silicon oxide. Alternatively, the dielectric layer 120 may include some combination of materials, for example a silicon nitride dielectric liner and a silicon oxide fill. After, excess dielectric material can be polished using known techniques until a topmost surface of the dielectric layer 120 is flush, or substantially flush, with topmost surfaces of the sacrificial gate lines 110.

As indicated above with respect to the gate cut opening, the gate cut region 122 is self-aligned between the gate spacers 112. As such, the length of the gate cut region 122, in the x-direction, is determined by the length of the sacrificial gate lines 110, or the distance between the gate spacers 112.

In contrast, a width of the gate cut region 122, in the y-direction, is flexible and dependent on cell design. For example, if the width of the gate cut region 122, in the y-direction, is too long, the remaining portions of the channel nanosheets 106 will be too small and negatively affect device performance. In contrast, if the width of the gate cut region 122, in the y-direction, is too short, it may be difficult to successfully replace the sacrificial 110 with a metal gate material, as described below. Further, the gate cut region 122 is necessary to facilitate successful replacement metal gate techniques, precisely define the channel regions, and ensure electrical isolation between source drain extension regions, as is discussed in greater detail below.

It is noted, after forming the gate cut region 122, remaining portions of the channel nanosheets 106 become, and are hereinafter referred to as, channel regions 124. It is further noted, the channel regions 124 refer to a portion of the channel nanosheets 106 between the salicide regions 118, as illustrated in FIG. 14.

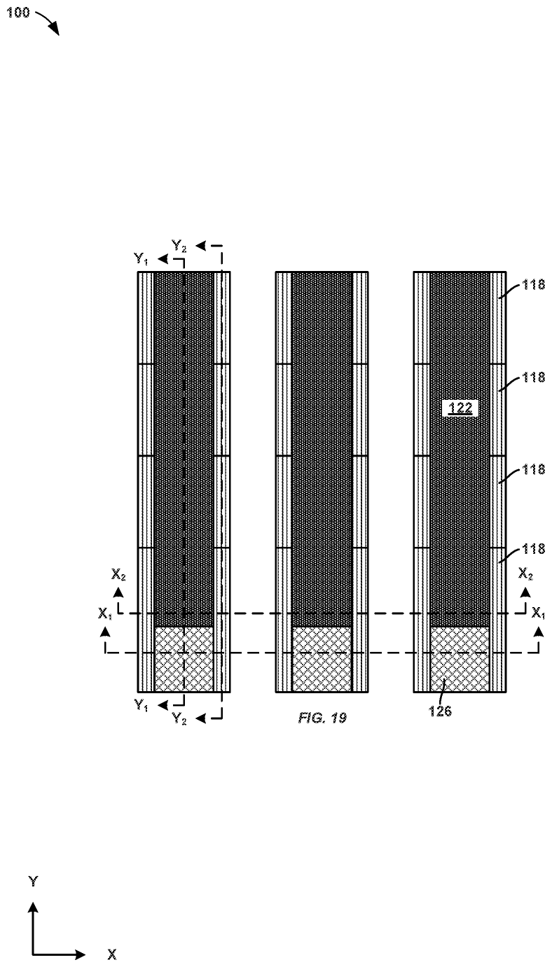

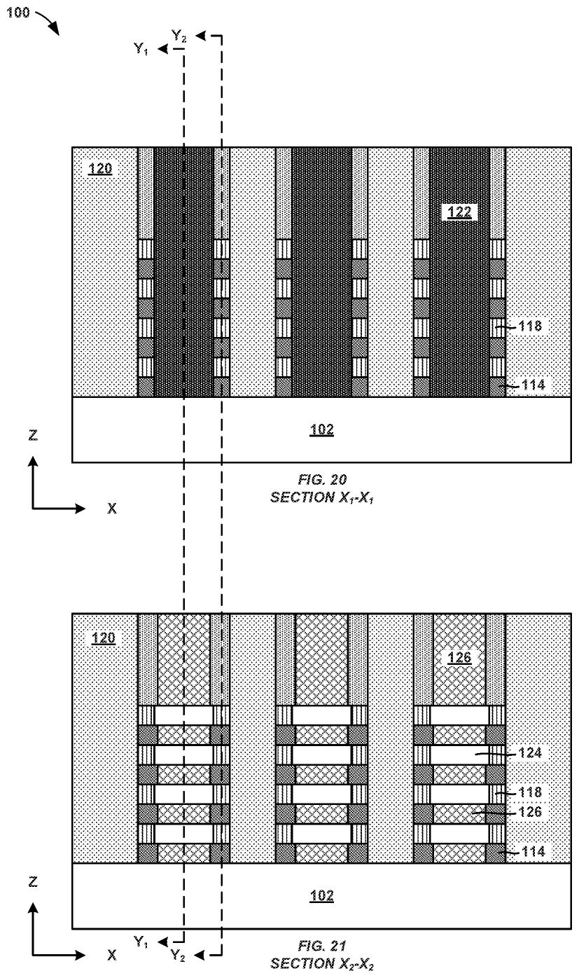

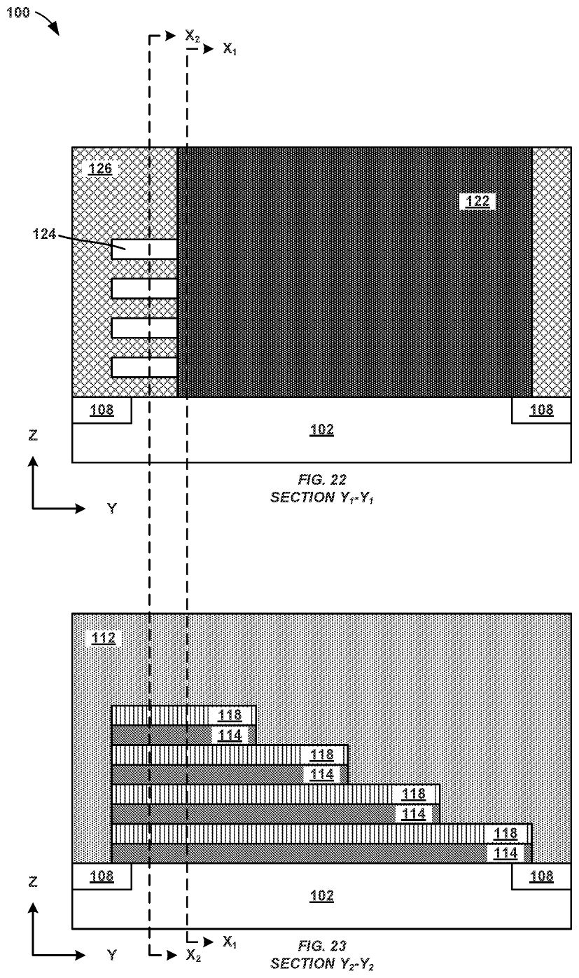

Referring now to FIGS. 19, 20, 21, 22, and 23, the structure 100 is shown after forming a gate conductor 126 according to an embodiment of the invention. FIG. 19 is a representative illustration of a top view of the structure 100 omitting some features as described above with reference to FIG. 1. FIG. 20 depicts a cross-sectional view of the structure 100 shown in FIG. 19 taken along line X₁-X₁. FIG. 21 depicts a cross-sectional view of the structure 100 shown in FIG. 19 taken along line X₂-X₂. FIG. 22 depicts a cross-sectional view of the structure 100 shown in FIG. 19 taken along line Y₁-Y₁. FIG. 23 depicts a cross-sectional view of the structure 100 shown in FIG. 19 taken along line Y₂-Y₂.

The gate conductor 126 is formed according to known replacement gate techniques. For example, the sacrificial gate lines 110 and the sacrificial nanosheets 104 are removed selective to the channel nanosheets 108, and the gate conductor 126 is formed between the gate spacers 112 and surrounding the channel nanosheets 108 in a typical gate-all-around fashion. Because the gate conductor 126 is formed after the gate cut region 120, the gate conductor 126 will only surround three sides of the channel nanosheets 108, as illustrated in FIG. 22.

In an embodiment, the gate conductor 126 is composed of an n-type work function metal. As used herein, an “n-type work function metal” is a metal that effectuates an n-type threshold voltage shift. “N-type threshold voltage shift” as used herein means a shift in the Fermi energy of an n-type semiconductor device towards a conduction band of silicon in a silicon-containing substrate of the n-type semiconductor device. The “conduction band” is the lowest lying electron energy band of the doped material that is not completely filled with electrons. In an embodiment, the work function of the n-type work function metal ranges from 4.1 eV to 4.3 eV. In an embodiment, the n-type work function metal is composed of at least one of TiAl, TaN, TiN, HfN, HfSi, or combinations thereof. The n-type work function metal can be formed using chemical vapor deposition atomic layer deposition, sputtering or plating.

In another embodiment, the gate conductor 126 may be a p-type work function metal. As used herein, a “p-type work function metal” is a metal that effectuates a p-type threshold voltage shift. In an embodiment, the work function of the p-type work function metal ranges from 4.9 eV to 5.2 eV. As used herein, “threshold voltage” is the lowest attainable gate voltage that will turn on a semiconductor device, for example, transistor, by making the channel of the device conductive. The term “p-type threshold voltage shift” as used herein means a shift in the Fermi energy of a p-type semiconductor device towards a valence band of silicon in the silicon containing substrate of the p-type semiconductor device. A “valence band” is the highest range of electron energies where electrons are normally present at absolute zero. In an embodiment, the p-type work function metal may be composed of titanium, titanium nitride or titanium carbide. The p-type work function metal may also be composed of TiAlN, Ru, Pt, Mo, Co and alloys and combinations thereof. In an embodiment, the p-type work function metal can be formed by, a physical vapor deposition method, such as sputtering, chemical vapor deposition or atomic layer deposition.

The gate conductor 126 can be formed by any deposition technique including, for example, chemical vapor deposition (CVD), plasma enhanced chemical vapor deposition (PECVD), physical vapor deposition (PVD), sputtering, or atomic layer deposition. It is critical to monitor and control forming of the gate conductor 126 to prevent pinch off and void formation between adjacent channel nanosheets 108.

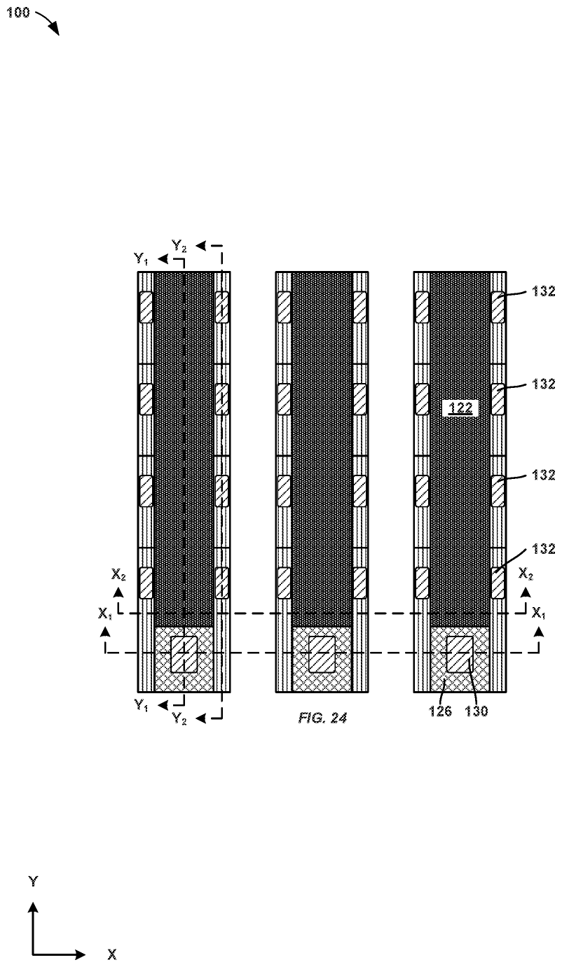

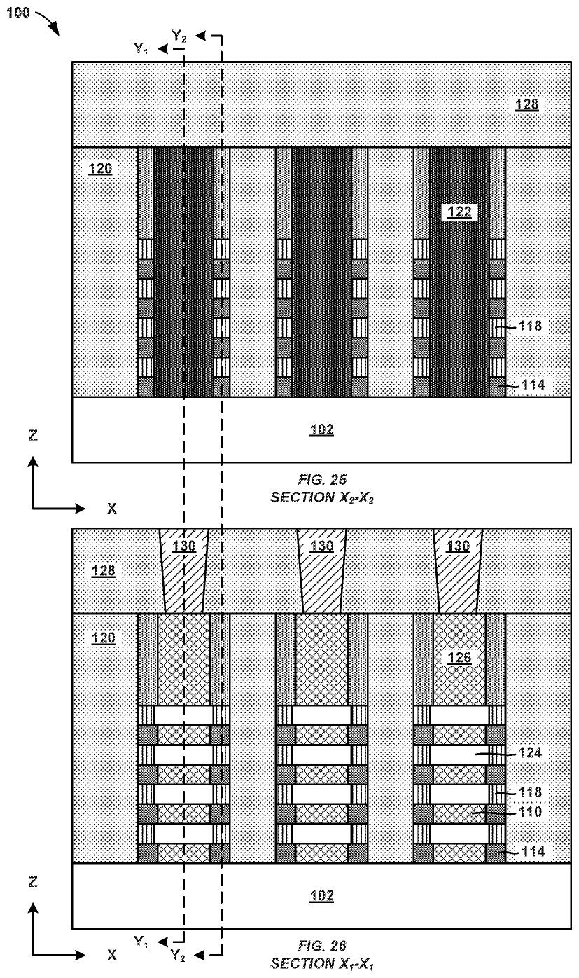

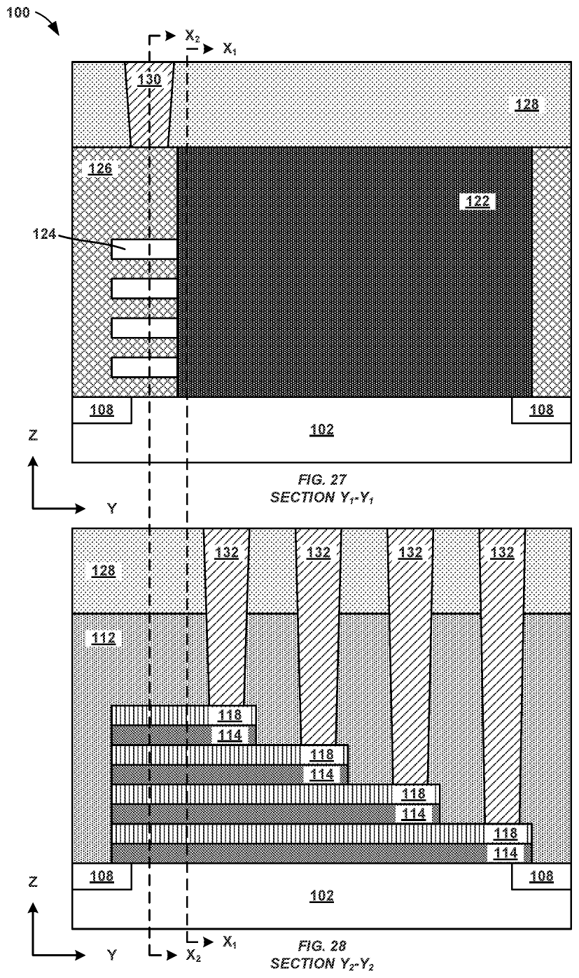

Referring now to FIGS. 24, 25, 26, 27, and 28, the structure 100 is shown after forming a middle-of-line dielectric 128, gate contacts 130, and source drain contacts 132 according to an embodiment of the invention. FIG. 24 is a representative illustration of a top view of the structure 100 omitting some features as described above with reference to FIG. 1. FIG. 25 depicts a cross-sectional view of the structure 100 shown in FIG. 24 taken along line X₁-X₁. FIG. 26 depicts a cross-sectional view of the structure 100 shown in FIG. 24 taken along line X₂-X₂. FIG. 27 depicts a cross-sectional view of the structure 100 shown in FIG. 24 taken along line Y₁-Yi. FIG. 28 depicts a cross-sectional view of the structure 100 shown in FIG. 24 taken along line Y₂-Y₂.

First, the middle-of-line dielectric 128 is blanket deposited across the entire structure 100. Like the dielectric layer 120, the middle-of-line dielectric 128 can be any known interlevel dielectric material. Next, gate contacts 130, and source drain contacts 132 are formed using typical patterning and damascene metallization techniques.

The gate contacts 130 and the source drain contacts 132 may include any suitable conductive material, such as, for example, titanium, titanium nitride, boron doped tungsten, or carbon doped tungsten. After filling, excess conductive material can be polished using known techniques until a topmost surface of the gate contacts 130 and the source drain contacts 132 are flush, or substantially flush, with topmost surfaces of the middle-of-line dielectric 128. It is noted that separate source drain contacts 132 are formed in contact with separate salicide regions 118, and thus separate channel regions 124. As such, because of the stepped formation of the salicide regions 118 (see FIGS. 18, 23, and 28), the source drain contacts 132 will have different heights, as illustrated in FIG. 28.

As illustrated in FIGS. 24, 25, 26, 27, and 28, the transistor structures represented by the structure 100 has some distinctive notable features.

First, the proposed structure enables separate source drain contacts 132 for each individual channel region 124. Doing so provides individual channel regions 124 in a stacked configuration allowing for higher device density. In an embodiment, the source drain contacts 132, and similarly each individual channel region 124, would be wired individually. Further, all channel regions 124 of the proposed structure would have a common gate conductor (126). In an alternative embodiment, one or more source drain contacts 132 may be wired together in the back-end-of-line to enable higher current transmission across multiple channel regions (124). In yet another embodiment, a merged contact can be formed in direct contact with multiple salicide regions 118.

For purposes of the present disclosure, it is critical that the salicide regions 118 are large enough to (a) conduct sufficient current to and from each individual channel region 124, and (b) minimize contact resistance between each salicide region 118 and each source drain contact 132.

Unlike conventional structures, the salicide regions 118 and the source drain contacts 132 of the structure 100 reduce resistance by enabling direct contact between the channel and the silicide. In typical devices, the channel is separated from any silicide by a source drain epitaxy.

For reference purposes measurements taken in the x-direction, perpendicular to the gate conductor 126, are herein referred to as “length”, while measurements taken in the y-direction, parallel to the gate conductor 126, are herein referred to as “width”.

In sum, for purposes of this description the structure 100 illustrated in the figures and described herein includes multiple gate-all-around transistor structures positioned adjacent, or next, to one another, and manufactured in a process flow. Embodiments of the present invention, and the detailed description provide above, are directed primarily at salicide source drain regions, and contact formation after a replacement metal gate is formed.

The descriptions of the various embodiments of the present invention have been presented for purposes of illustration, but are not intended to be exhaustive or limited to the embodiments disclosed. Many modifications and variations will be apparent to those of ordinary skill in the art without departing from the scope and spirit of the invention. The terminology used herein was chosen to best explain the principles of the embodiment, the practical application or technical improvement over technologies found in the marketplace, or to enable others of ordinary skill in the art to understand the embodiments disclosed herein.

What is claimed is:

1. A gate-all-around transistor structure comprising:
a channel region surrounded on three sides by a gate conductor; and
a pair of salicide regions extending from opposite ends of the channel region in a direction parallel with the gate conductor.

2. The structure according to claim 1, further comprising:
a pair of contact structures contacting uppermost surfaces of the pair of salicide regions.

3. The structure according to claim 1, further comprising:
a gate cut region arranged between gate spacers and aligned with the gate conductor, wherein the gate cut region direct contacts a sidewall of the channel region.

4. The structure according to claim 1, wherein the pair of salicide regions are arranged above a pair of inner spacers.

5. The structure according to claim 1, wherein a thickness of each of the plurality of channel regions is equal to a thickness of each of the plurality of salicide regions.

6. The structure according to claim 1, wherein each of the pair of salicide regions are arranged directly beneath a gate spacer.

7. A gate-all-around transistor structure comprising:
a plurality of channel regions surrounded on three sides by a gate conductor; and
a plurality of salicide regions extending from opposite ends of the plurality of channel regions in a direction parallel with the gate conductor.

8. The structure according to claim 7, further comprising:
individual contact structures contacting uppermost surfaces of each of the plurality of salicide regions.

9. The structure according to claim 8, wherein at least two of the individual contact structures comprise different heights.

10. The structure according to claim 7, further comprising:
a gate cut region arranged between gate spacers and aligned with the gate conductor.

11. The structure according to claim 7, wherein each of the plurality of salicide regions are arranged one above the other and separated by a plurality of inner spacers.

12. The structure according to claim 7, wherein a thickness of each of the plurality of channel regions is equal to a thickness of each of the plurality of salicide regions.

13. The structure according to claim 7, wherein each of the plurality of channel regions are arranged vertically one above the other.

14. A gate-all-around transistor structure comprising:
a plurality of nanosheet channel regions surrounded on three sides by a gate conductor; and
a pair of salicide regions extending from opposite ends of each of the plurality of channel regions in a direction parallel with the gate conductor, wherein each pair of salicide regions extend different distances from the opposite ends of each of the plurality of channel regions.

15. The structure according to claim 14, further comprising:
a pair of contact structures contacting uppermost surfaces of the pair of salicide regions.

16. The structure according to claim 15, wherein at least two of the plurality of contact structures comprise different heights.

17. The structure according to claim 14, further comprising:
a gate cut region arranged between gate spacers and aligned with the gate conductor.

18. The structure according to claim 14, wherein each of the plurality of salicide regions are arranged one above the other and separated by a plurality of inner spacers.

19. The structure according to claim 14, wherein a thickness of each of the plurality of channel regions is equal to a thickness of each of the plurality of salicide regions.

20. The structure according to claim 14, wherein each of the plurality of channel regions are arranged vertically one above the other.
